(19) United States
(12) Patent Application Publication
(10) Pub. No.: US 2025/0131176 A1
(43) Pub. Date: Apr. 24, 2025

(54) HIGH-CURRENT TOLERANT IC DESIGN WITH PLACEMENT-AWARE ANTENNA DIODE INSERTION

(71) Applicant: INTERNATIONAL BUSINESS MACHINES CORPORATION, ARMONK, NY (US)

(72) Inventors: David Wolpert, POUGHKEEPSIE, NY (US); Miles C. Pedrone, Highland, NY (US); Brian Veraa, Round Rock, TX (US)

(21) Appl. No.: 18/493,037

(22) Filed: Oct. 24, 2023

(51) Int. Cl. G06F 30/392; G06F 30/398

(52) U.S. Cl. CPC G06F 30/392; G06F 30/398

(57) ABSTRACT

A hierarchical integrated circuit design includes at least an upper hierarchy level, an intermediate hierarchy level, and a lower hierarchy level. The lower hierarchy level includes a design entity including an antenna diode. Processing circuitry of a data processing system performs placement for integrated circuitry bounded by the design entity. Performing placement for the integrated circuitry includes determining whether or not an antenna cell containing the antenna diode has any proximate cell containing an antenna diode or other diffusion region connected to a chip package pin and, based on a determination that the antenna cell has an adjoining cell containing a diffusion region connected to a chip package pin, automatically padding the antenna cell with sufficient padding to satisfy a minimum antenna cell spacing rule and assigning the antenna cell location within a floorplan of the integrated circuit design such that electrostatic discharge events occurring on chip package pins will not damage the chip.

### BACKGROUND OF THE INVENTION

The present invention relates in general to integrated circuitry, and more specifically, to techniques for designing integrated circuitry that is tolerant of electrostatic discharge (ESD) and other high-current events.

The development of an integrated circuit involves several stages from logic design through fabrication. The integrated circuit design may be logically organized utilizing several levels of design hierarchy in which one or more entities at the lowest level of the design hierarchy are nested within one or more entities at successively higher levels. This hierarchical organization of the overall integrated circuit design simplifies the logical and physical design and testing performed at different stages of the development of the integrated circuit. As one example, the design hierarchy can include a chip level, which contains a lower-level “core level,” which contains a lower-level “unit level,” which contains a yet lower-level “random logic macro (RLM) level.” Generally, a cell or macro can be regarded as a subset of the integrated circuit of a given scope. Thus, for example, in some design hierarchies, each macro may comprise one or more cells.

It is desirable for integrated circuits to have a high tolerance for transient high-current conditions that may occur on connections between an integrated circuit and its package. For example, a high-current condition may occur due to an electrostatic discharge (ESD) or electrical overstress (EOS) event in which the current applied to the integrated circuit may approach multiple amperes, rather than the milliamperes at which an integrated circuit typically operates. A similar high-current condition can be experienced, for example due to an abnormally high-current condition on an input/output (I/O) pin of a driver circuit. In general, it is desirable to evaluate an integrated circuit design for its tolerance to high-current conditions prior to fabrication and even prior to preparing the photo masks utilized in fabrication.

During the design of macros, diodes (sometimes referred to as “antenna diodes”) are often manually added to the layout of the macro to provide a contact from a metal layer to a diffusion layer of an integrated circuit for manufacturing purposes. The contact provided by an antenna diode provides a path for the charge on a metal layer to be dissipated without damaging transistor gates or other circuit features implemented on the semiconductor substrate of the integrated circuit.

In addition, some macro designs may call for “tying off” or “tying down” one or more nets included in the macro. For example, a net may be “tied off” or “tied down” by connecting the net to a gate or circuit element (e.g., an antenna diode) directly connected to a constant signal (e.g., a power or ground supply rail) rather than to a signal that switches (e.g., an output of a logic gate). Gates may be tied to a supply rail for a variety of reasons, such as not needing to use a portion of a circuit in some situations. In such a situation, leaving an input floating could cause undesirable effects in downstream circuits, such as inefficient power consumption or generation of incorrect logic values. To avoid such problems, the input can be tied to a specific voltage (commonly provided by a supply rail), which depends on the polarity requirement of the unused input. The unused input can have a polarity requirement because even though a signal/gate may be unused, the signal or gate may be one of multiple inputs to a subsequent gate, and that subsequent gate's function may require a specific polarity for the unused input. Similarly, other logic gates will have diffusion regions that are tied to supply or ground rails in order to source or sink current, respectively, for the functional operation of the logic gate.

To avoid high-current induced failures caused, for example, by the development of large voltage potentials between local diffusion contacts, placements of antenna diodes typically follow a minimum distance (spacing) rule. The minimum distance rule can be described generally as a requirement that antenna diodes having different polarities or antenna diodes connected to different nets with different polarities are spaced apart from one another by at least a distance threshold. Additionally, one or both of these diffusion contacts may also be directly connected to a package pin through a supply or ground rail, providing similarly large voltage potentials between nearby diffusion contacts which must be avoided to ensure chip reliability.

### SUMMARY OF THE INVENTION

The present application recognizes that passing a compliance check for placement of antenna diodes at one level of the design hierarchy does not guarantee compliance with placement rules at a higher hierarchy level. Thus, for example, an internal net at a lower level of design hierarchy (e.g., within a RLM) can pass a compliance check for placement of antenna diodes at that lower level of design hierarchy, but can fail the compliance check at a higher level of design hierarchy, such as the unit level or chip level. As one example, failure of the compliance check can be caused by a tie wire (or other connection to a chip package pin) at the higher level that may be unknown at the lower level of design hierarchy.

The present application further appreciates that such compliance failures can be costly and can require post-process fixes involving, for example, addition of inverters or buffers or manual movement of antenna diodes within the integrated circuit design at various layers of hierarchy.

The present application therefore appreciates that it would be useful and desirable to provide a correct-by-construction solution that enables a hierarchical design to be effectively checked for compliance with placement rules for antenna diodes.

In at least one embodiment, a hierarchical integrated circuit design includes at least an upper hierarchy level, an intermediate hierarchy level, and a lower hierarchy level. The lower hierarchy level includes a design entity including an antenna diode. Processing circuitry of a data processing system performs placement for integrated circuitry bounded by the design entity. Performing placement for the integrated circuitry includes determining whether or not an antenna cell containing the antenna diode has any adjoining or nearby cell containing an antenna diode or other diffusion region connected to a chip package pin, and, based on a determination that the antenna cell has an adjoining or nearby cell containing an antenna diode or other diffusion region connected to a chip package pin, automatically padding the antenna cell with sufficient padding to satisfy a minimum antenna cell spacing rule and assigning the antenna cell location within a floorplan of the integrated circuit design.

### BRIEF DESCRIPTION OF THE DRAWINGS

FIG. 1 is a high-level block diagram of an exemplary data processing environment in accordance with one or more embodiments;

FIG. 2 is a high-level block diagram of an exemplary integrated circuit design hierarchy in accordance with one or more embodiments;

FIG. 3A illustrates exemplary selection criteria for antenna cell placement solution(s) in accordance with one or more embodiments;

FIG. 3B is a high-level logical flowchart for placing net-terminating elements in an integrated circuit design in accordance with one or more embodiments; and

FIG. 4 illustrates an exemplary design process in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as integrated circuit design tool 150 enabling development of an integrated circuit design 200. In addition to integrated circuit design tool 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and integrated circuit design tool 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

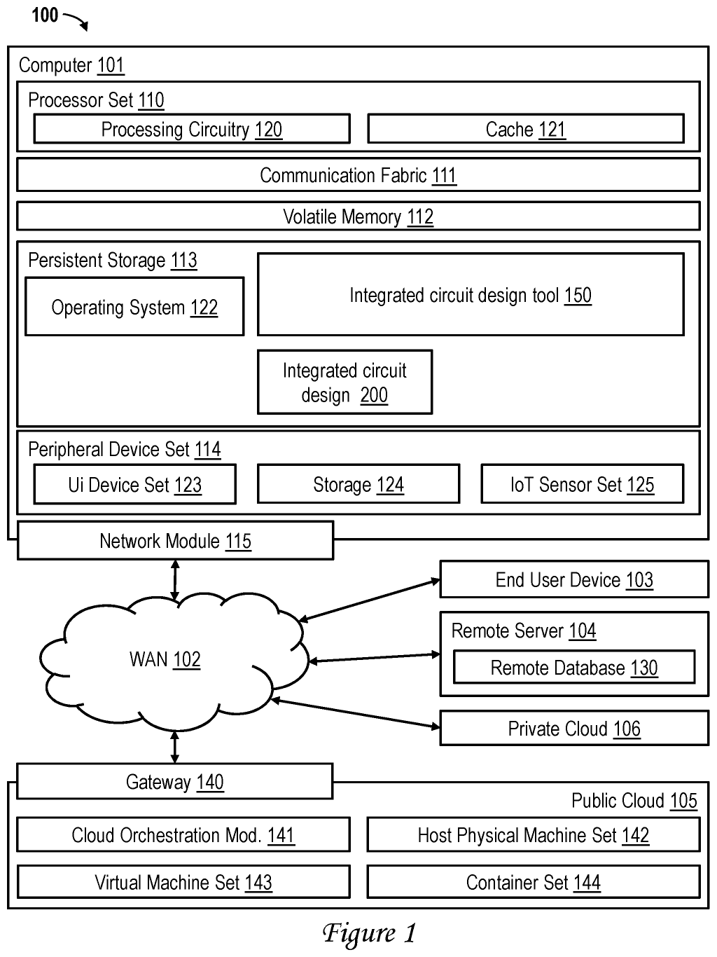

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in integrated circuit design tool 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet-of-Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the Internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those of ordinary skill in the art will appreciate that the architecture and components of a data processing environment can vary between embodiments. Accordingly, the exemplary computing environment 100 given in FIG. 1 is not meant to imply architectural limitations with respect to the claimed invention.

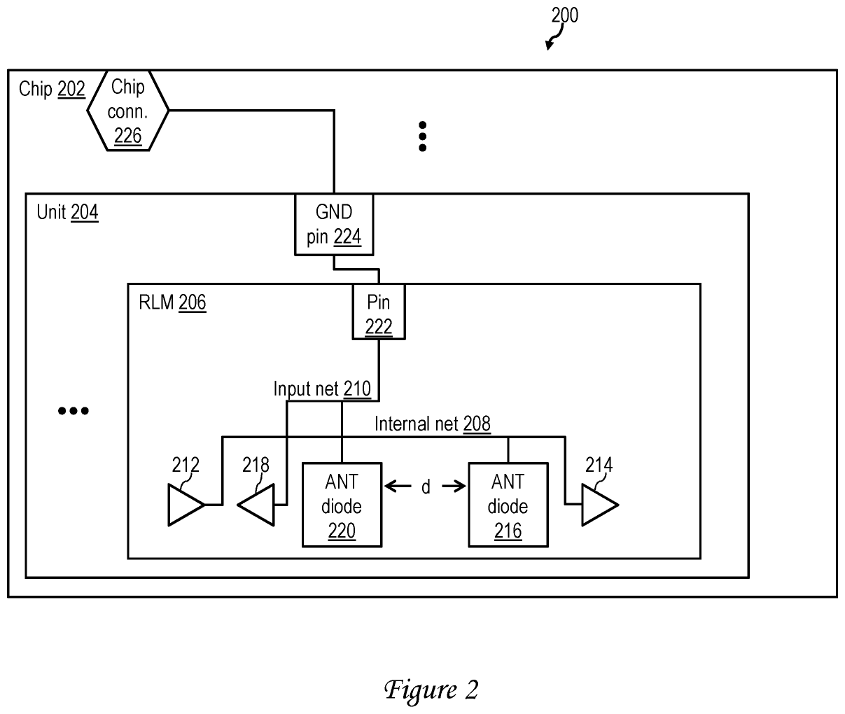

Referring now to FIG. 2, there is depicted an exemplary integrated circuit design 200 in accordance with one or more embodiments. Integrated circuit design 200 can be represented, for example, by one or more files within a storage device of a data processing system, as discussed above with reference to FIG. 1. Integrated circuit design 200 includes a design hierarchy having multiple levels. In the depicted example, the design hierarchy includes, at a highest level, a chip entity 202, which in turn includes, at an intermediate level of the design hierarchy, a unit entity 204 that in turn includes a random logic macro (RLM) entity 206 at a lower level of the design hierarchy. Those skilled in the art will appreciate that integrated circuit design 200 can include additional levels of design hierarchy and multiple entities at each of one or more lower levels of the design hierarchy. By way of illustration rather than limitation, unit entity 204 may include one or more RLM entities in addition to RLM entity 206, and chip entity 202 may include one or more unit entities in addition to unit entity 204.

As further illustrated in FIG. 2, RLM entity 206 includes an internal network (net) 208 coupling one or more internal components of RLM entity 206. In the illustrated example, these internal components include a first gate 212, a second gate 214, and a first antenna diode 216. RLM entity 206 additionally includes a different input net 210 having one or more connections to features internal and external to RLM entity 206. In this example, the components coupled to input net 210 include an input gate 218, a second antenna diode 220, a RLM input pin 222, a unit ground pin 224, and a chip connection 226 (e.g., a controlled collapse chip connection (C4) pin). It should be noted that unit ground pin 224 and chip connection 226 are external to RLM unit 206 at higher levels of the design hierarchy. Internal net 208 and input net 210 have different (opposite) polarities. It should be appreciated that the type and number of components coupled to input net 210 and internal net 208 are not limited to that shown in FIG. 2.

Based on placement information of integrated circuit design 200, antenna diode 220 is spaced apart from the antenna diode 116 by a distance (d), which may be sufficient to satisfy a compliance check for antenna diode spacing based on the design information associated with RLM entity 206 considered in isolation. However, if integrated circuit design 200 is considered as a whole, spacing antenna diodes 216 and 220 by distance d may be insufficient to satisfy the compliance check for antenna diode spacing due to the fact that chip connection 226 can serve as a potential source of transient high-current (e.g., ESD) events to RLM entity 206 due to the electrical connection of chip connection 226 to input net 210. Due this connection between chip connection 226 and input net 210, a transient high current can be delivered directly to antenna diode 220. As a result, an ESD fail region can be created within integrated circuit design 200 due to the opposing polarities and close spacing of antenna diodes 216 and 220.

Conventional integrated circuit design techniques can fail to detect such an ESD fail region when the potential source of a transient high-current event and the termination of the net are separated by one or more levels of design hierarchy. One known technique for avoiding inadvertent creation of ESD fail regions is to simply place elements at each level of the design hierarchy utilizing conservative spacing rules, for example, ensuring that placement of each antenna diode within a given level of hierarchy satisfies the minimum ESD distance threshold. However, such a conservative design methodology can impose a density penalty on an integrated circuit design and determine an artificially large minimum overall size of entities at one or more levels of the design hierarchy.

According to one or more embodiments, inadvertent creation of ESD fail regions can instead be avoided by employing improved integrated circuit design techniques that ensure that placement of antenna diodes or other elements terminating nets susceptible to transient high-current events is correct-by-construction. The resulting integrated circuit designs are thus capable of reducing or avoiding damage to the integrated circuit that can otherwise result from transient high-current events due to cross-hierarchy tie nets.

In at least one embodiment, integrated circuit design tool 150 enables improved placement of net-terminating elements (e.g., antenna diodes) by judicious selection and/or ordering of placement solutions as needed to satisfy minimum spacing requirements. These placement solutions can include checking at the cell level of the design hierarchy for placements of antenna diodes that may violate minimum spacing rules and, if needed, proactively updating antenna diode placements and/or cell properties with minimum placement fills, and, if needed, increasing padding in each antenna cell enough to satisfy minimum spacing requirements.

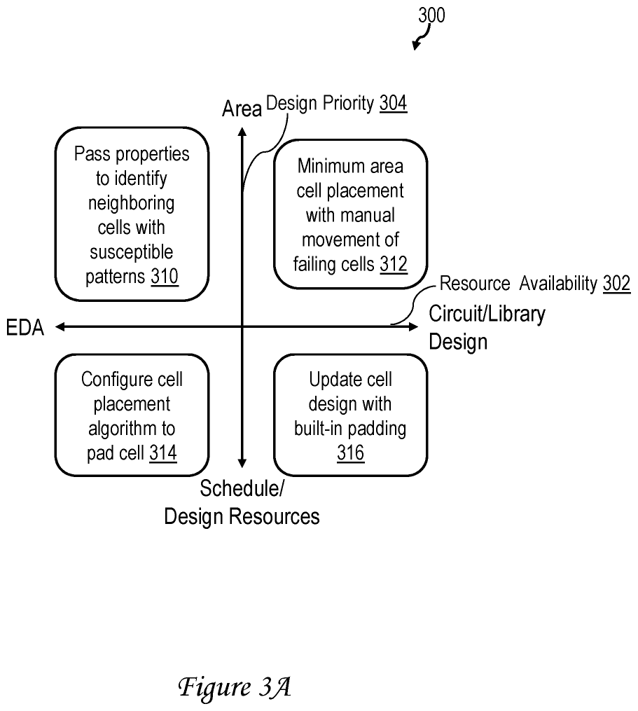

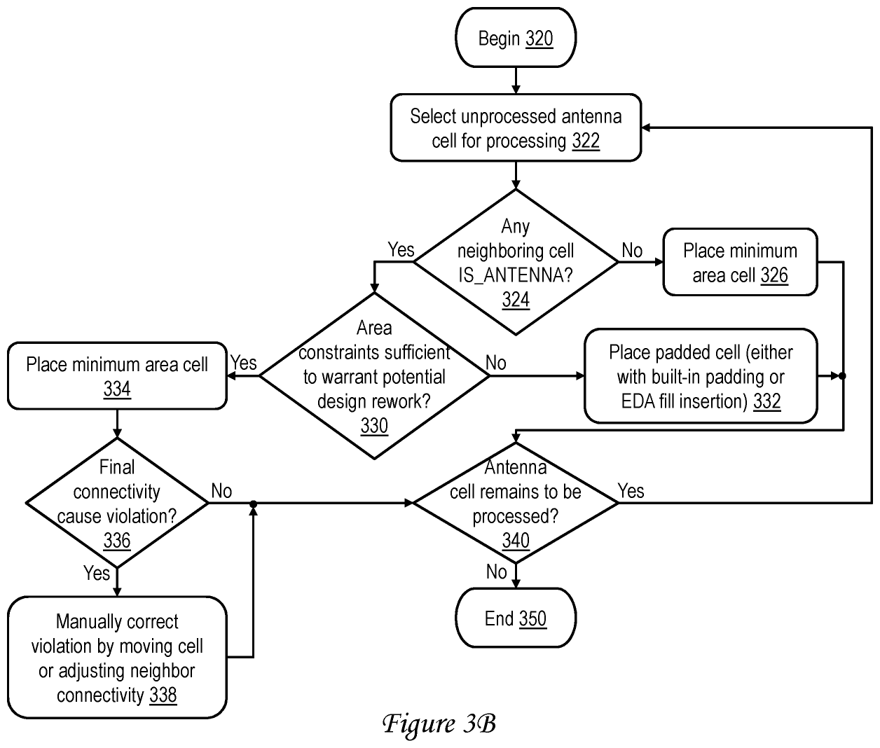

FIG. 3A illustrates a grid 300 of criteria that can be utilized to select and prioritize antenna cell placement solution(s) in accordance with one or more embodiments. Grid 300 includes a resource availability axis 302 representing the range of design resources available to improve cell placement. Antenna cell placement solutions toward the left end of resource availability axis 302 require greater availability and use of electronic design automation (EDA) tools to improve antenna cell placement, while those toward the right end of resource availability axis 302 rely upon greater enhancements to circuit and library designs to improve antenna cell placement.

Grid 300 additionally includes a design priority axis 304 representing a range of various competing design priorities for an integrated circuit design, which in this case include the minimization of the overall area (“footprint”) of the integrated circuit design and achieving a shorter design schedule and thus minimizing utilization of design resources (e.g., engineering hours, computational resources, etc.). Thus, in FIG. 3A antenna cell placement solutions toward the top of design priority axis 304 tend to prioritize minimization of circuit area over a shorter design schedule and/or reduction in the use of design resources, while antenna cell placement solutions toward the bottom of design priority axis 304 tend to make the opposite prioritization.

Within grid 300, a first antenna cell placement solution 310 toward the left end of resource availability axis 302 and the top end of design priority axis 304 involves configuring EDA tools, such as integrated circuit design tool 150, to pass cell properties between neighboring placement cells and cell placement tooling to identify patterns of cells that are susceptible to violation of a minimum antenna cell distance rule. A second antenna cell placement solution 312 toward the right end of resource availability axis 302 and the top end of design priority axis 304 entails implementation of a minimum area cell placement through manual (as opposed to automated) placement of antenna cells that violate the minimum antenna cell spacing rule. Grid 300 additionally includes a third antenna cell placement solution 314 toward the left end of resource availability axis 302 and the bottom end of design priority axis 304. Third antenna cell placement solution 314 configures the cell placement algorithm of an EDA tool such as integrated circuit design tool 150 to pad each antenna cell with appropriate fill cell neighbors such that the minimum antenna cell spacing rule is satisfied. A fourth antenna cell placement solution 316 toward the right end of resource availability axis 302 and bottom end of design priority axis 304 involves updating the design of one or more antenna cells to include built-in padding within the cell design itself such that the minimum antenna cell spacing rule is satisfied. As will be appreciated by those skilled in the art, a given embodiment of an integrated circuit design process may employ one or more of solutions 310, 312, 314, and 316 (and possibly additional antenna cell placement solutions).

With reference now to FIG. 3B, there is illustrated a high-level logical flowchart of an exemplary process for placing cells containing net-terminating elements (e.g., antenna diodes) in an integrated circuit design in accordance with one or more embodiments. The process can be performed, for example, by processing circuitry 120 of computer 101 through the execution of integrated circuit design tool 150 in order to generate and/or refine integrated circuit design 200. It should be appreciated that the method depicted in FIG. 3B is only one of multiple possible methods that can be implemented based on the design trade-offs and placement solutions represented by grid 300 of FIG. 3A.

The process of FIG. 3B starts at block 320, which illustrates processing circuitry 120 beginning an antenna cell placement routine for a given design entity at a lower level of a hierarchical integrated circuit design. For example, in integrated circuit 200 of FIG. 2, the given entity may be unit entity 204 or RLM entity 206. Integrated circuit design tool 150 preferably initiates the antenna diode placement routine following development of the logic design of integrated circuit design 200 in which one or more antenna diodes (e.g., antenna diodes 220 and 216) are instantiated within the given design entity and then logically connected to internal nets (e.g., internal net 208) or externally connected nets (e.g., input net 210). As noted above, the various nets of the given design entity may have opposite polarities.

The process of FIG. 3B then proceeds from block 320 to block 322, which illustrates processing circuitry 120 selecting for processing an antenna cell of the given design entity, that is, a cell containing an antenna diode. At block 324, processing circuitry 120 determines whether any neighboring cell adjoining the selected antenna cell is marked (e.g., by an associated IS_ANTENNA property) as an antenna cell containing an antenna diode or other diffusion region connected to a chip package pin and thus has a potential to cause a violation of a minimum spacing rule for antenna diodes. It should be appreciated that in prior art systems, cell properties, such as whether a cell contains an antenna diode, are not propagated during placement performed at lower levels of the design hierarchy (e.g., at RLM level or unit level). In response to a negative determination at block 324, processing circuitry 120 sets the cell size of the antenna cell to a minimum cell area for the selected technology node (e.g., 5 nm, 7 nm, etc.) and places the minimum area (i.e., unpadded) antenna cell within the floorplan of the integrated circuit design 200 (block 326). The process then proceeds from block 326 to block 340, which is described below.

In response to an affirmative determination at block 324, processing circuitry 120 additionally determines at block 330 whether or not area constraints within the given design entity, and particularly, in the local region of the design entity surrounding the selected antenna cell, are sufficient to warrant potentially reworking the design of integrated circuit design 200. For example, the determination shown at block 330 can include determining whether the addition of padding to the selected antenna cell and its neighboring antenna cell(s) sufficient to satisfy the minimum antenna cell spacing rule would cause the area of the given design entity (or a subset thereof) to exceed an area threshold. In response to a negative determination at block 330, the process passes to block 332, which depicts processing circuitry 120 placing a padded antenna cell within the floorplan of integrated circuit design 200. As noted, in various embodiments, the padding, which is sufficient to satisfy the minimum antenna cell spacing rule, can be either built into the antenna cell itself or added to the boundary of the antenna cell by EDA fill insertion. Following block 332, the process of FIG. 3B proceeds to block 340, which is described below.

Returning to block 330, in response to a determination that area constraints are sufficient to warrant potential design rework, the process proceeds to block 334, which illustrates processing circuitry 120 setting the cell size of the antenna cell to a minimum cell area for the selected technology node (i.e., the antenna cell is unpadded) and placing the minimum area antenna cell within the floorplan of the integrated circuit design 200. Processing circuitry 120 additionally determines at block 336 whether or not the final connectivity of the neighboring cell causes placement of the minimum area antenna cell to violate the minimum antenna cell spacing rule, for example, by being too close to a diffusion region of another net connected to a chip package pin. If not, the process proceeds to block 340, which is described below. If, however, processing circuitry 120 detects violation of the minimum antenna cell spacing rule at block 336, processing circuitry 120 initiates manual correction of the violation by moving the selected antenna cell within the floorplan of the integrated circuit design and/or adjusting connectivity of a neighboring cell such that the spacing of the selected antenna cell, or nearby cell causing the violation detected in block 336, does not result in any additional spacing violations for other diffusion regions that may also be connected to chip package pins (block 338). The process then proceeds to block 340.

At block 340, processing circuitry 120 determines at block 340 whether or not any antenna cells within the given design entity remain to be processed. If not, the process of FIG. 3B ends at block 350. In response to a determination at block 340 that one or more antenna cells within the given design entity have not yet been processed, the process returns to block 322, which has been described.

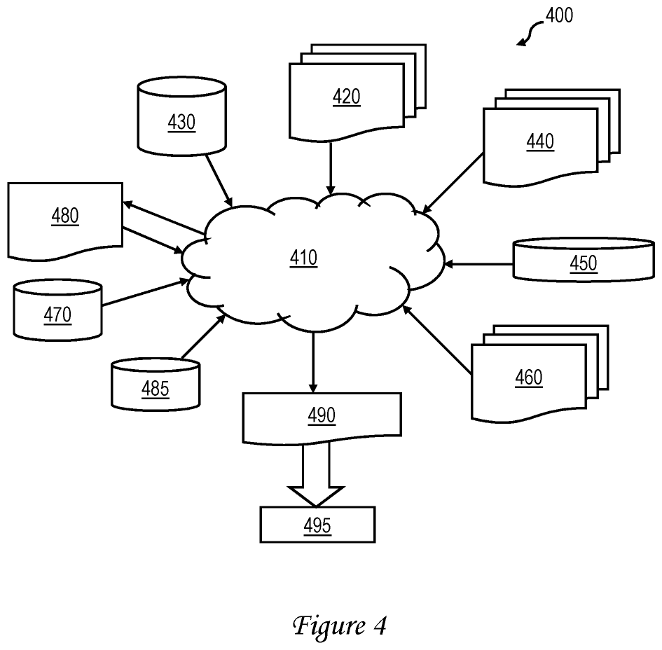

Referring now to FIG. 4, there is depicted a block diagram of an exemplary design flow 400 used for example, in semiconductor IC logic design, simulation, test, layout, and manufacture. As one example, design flow 400 can be utilized to design, simulation, test, layout, and manufacture integrated circuit design 200 of FIG. 2. Design flow 400 may in part be performed through execution of integrated circuit design tool 150 of FIG. 1. Design flow 400 includes processes, machines and/or mechanisms for processing design structures or devices to generate logically or otherwise functionally equivalent representations of the design structures and/or devices described above. The design structures processed and/or generated by design flow 400 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 400 may vary depending on the type of representation being designed. For example, a design flow 400 for building an application specific IC (ASIC) may differ from a design flow 400 for designing a standard component or from a design flow 400 for instantiating the design into a programmable array, for example a programmable gate array (PGA) or a field programmable gate array (FPGA) offered by Altera® Inc. or Xilinx® Inc.

FIG. 4 illustrates multiple such design structures including an input design structure 420 that is preferably processed by a design process 410. Design structure 420 may be a logical simulation design structure generated and processed by design process 410 to produce a logically equivalent functional representation of a hardware device. Design structure 420 may also or alternatively comprise data and/or program instructions that when processed by design process 410, generate a functional representation of the physical structure of a hardware device. Whether representing functional and/or structural design features, design structure 420 may be generated using electronic computer-aided design (ECAD) such as implemented by a core developer/designer. When encoded on a machine-readable data transmission, gate array, or storage medium, design structure 420 may be accessed and processed by one or more hardware and/or software modules within design process 410 to simulate or otherwise functionally represent an electronic component, circuit, electronic or logic module, apparatus, device, or system such as those shown herein. As such, design structure 420 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 410 preferably employs and incorporates hardware and/or software modules for synthesizing, translating, or otherwise processing a design/simulation functional equivalent of the components, circuits, devices, or logic structures shown herein to generate a netlist 480 which may contain design structures such as design structure 420. Netlist 480 may comprise, for example, compiled or otherwise processed data structures representing a list of wires, discrete components, logic gates, control circuits, I/O devices, models, etc. that describes the connections to other elements and circuits in an integrated circuit design. Netlist 480 may be synthesized using an iterative process in which netlist 480 is resynthesized one or more times depending on design specifications and parameters for the device. As with other design structure types described herein, netlist 480 may be recorded on a machine-readable storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, or buffer space.

Design process 410 may include hardware and software modules for processing a variety of input data structure types including netlist 480. Such data structure types may reside, for example, within library elements 430 and include a set of commonly used elements, circuits, and devices, including models, layouts, and symbolic representations, for a given manufacturing technology (e.g., different technology nodes, 7 nm, 10 nm, 20 nm, 30 nm, etc.). The data structure types may further include design specifications 440, characterization data 450, verification data 460, design rules 470, and test data files 485 which may include input test patterns, output test results, and other testing information. Design process 410 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 410 without deviating from the scope and spirit of the invention. Design process 410 may also include modules for performing standard circuit design processes such as timing analysis, verification, design rule checking, place and route operations, etc.

Design process 410 employs and incorporates logic and physical design tools such as HDL compilers and simulation model build tools to process design structure 420 together with some or all of the depicted supporting data structures along with any additional mechanical design or data (if applicable), to generate a second design structure 490. Design structure 490 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 420, design structure 490 preferably comprises one or more files, data structures, or other computer-encoded data or instructions that reside on transmission or data storage media and that when processed by an ECAD system generate a logically or otherwise functionally equivalent form of one or more of the embodiments of the invention shown herein. In one embodiment, design structure 490 may comprise a compiled, executable HDL simulation model that functionally simulates one or more of the devices shown herein.

Design structure 490 may also employ a data format used for the exchange of layout data of integrated circuits and/or symbolic data format (e.g., information stored in a GDSII (GDS2), GL1, OASIS, map files, or any other suitable format for storing such design data structures). Design structure 490 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown herein. Design structure 490 may then proceed to a stage 495 where, for example, design structure 490: proceeds to tape-out, is released to manufacturing, is released to a mask house, is sent to another design house, is sent back to the customer, etc.

As has been described, in at least one embodiment, a hierarchical integrated circuit design includes at least an upper hierarchy level, an intermediate hierarchy level, and a lower hierarchy level. The lower hierarchy level includes a design entity including an antenna diode. Processing circuitry of a data processing system performs placement for integrated circuitry bounded by the design entity. Performing placement for the integrated circuitry includes determining whether or not an antenna cell containing the antenna diode has any adjoining cell containing an antenna diode or other diffusion region connected to a chip package pin and, based on a determination that the antenna cell has an adjoining cell containing an antenna diode or other diffusion region connected to a chip package pin, automatically padding the antenna cell with sufficient padding to satisfy a minimum antenna cell spacing rule and assigning the antenna cell location within a floorplan of the integrated circuit design.

The present invention may be implemented as a method, a system, and/or a computer program product. The computer program product may include a storage device having computer-readable program instructions (program code) thereon for causing a processor to carry out aspects of the present invention. As employed herein, a “storage device” is specifically defined to include only statutory articles of manufacture and to exclude signal media per se, transitory propagating signals per se, and energy per se.

Aspects of the present invention are described herein with reference to flowchart illustrations and/or block diagrams that illustrate the architecture, functionality, and operation of possible implementations of systems, methods, and computer program products according to various embodiments. It will be understood that each block of the block diagrams and/or flowcharts and combinations of blocks in the block diagrams and/or flowcharts can be implemented by special purpose hardware-based systems and/or program code that perform the specified functions. While the present invention has been particularly shown as described with reference to one or more preferred embodiments, it will be understood by those skilled in the art that various changes in form and detail may be made therein without departing from the spirit and scope of the invention.

The figures described above and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms and that multiple of the disclosed embodiments can be combined. Lastly, the use of a singular term, such as, but not limited to, “a” is not intended as limiting of the number of items.

What is claimed is:

1. A method, in a data processing system including processing circuitry, of performing placement for a hierarchical integrated circuit design, the method comprising:
in a hierarchical integrated circuit design including at least an upper hierarchy level, an intermediate hierarchy level, and a lower hierarchy level, said lower hierarchy level including a design entity including at an antenna diode, the processing circuitry performing placement for integrated circuitry bounded by the design entity, wherein performing placement includes:
the lower level determining whether or not an antenna cell containing the antenna diode has any adjoining cell containing a diffusion region connected to a chip package pin; and
based on a determination that the antenna cell has an adjoining cell containing a diffusion region connected to a chip package pin, the processing circuitry automatically padding the antenna cell with sufficient padding to satisfy a minimum antenna cell spacing rule and assigning the antenna cell location within a floorplan of the integrated circuit design.

2. The method of claim 1, wherein automatically padding the antenna cell includes updating a design of the antenna cell to include the padding.

3. The method of claim 1, wherein automatically padding the antenna cell includes surrounding the antenna cell with the padding.

4. The method of claim 1, wherein:
the automatically padding comprises automatically padding the antenna cell based on determining that an area constraint of the design entity is satisfied.

5. The method of claim 4, further comprising:
based on determining that the area constraint of the design entity is not satisfied, placing the antenna cell without padding in the floorplan of the integrated circuit design.

6. The method of claim 1, wherein the diffusion region is an antenna diode.

7. A program product, comprising:
a storage device; and
program code stored within the storage device and executable by processing circuitry of a data processing system to cause the data processing system to perform placement for a hierarchical integrated circuit design including at least an upper hierarchy level, an intermediate hierarchy level, and a lower hierarchy level, said lower hierarchy level including a design entity including at an antenna diode, wherein the program code causes the data processing system to perform placement for integrated circuitry bounded by the design entity by:
determining whether or not an antenna cell containing the antenna diode has any adjoining cell containing a diffusion region connected to a chip package pin; and
based on a determination that the antenna cell has an adjoining cell containing a diffusion region connected to a chip package pin, automatically padding the antenna cell with sufficient padding to satisfy a minimum antenna cell spacing rule and assigning the antenna cell location within a floorplan of the integrated circuit design.

8. The program product of claim 7, wherein automatically padding the antenna cell includes updating a design of the antenna cell to include the padding.

9. The program product of claim 7, wherein automatically padding the antenna cell includes surrounding the antenna cell with the padding.

10. The program product of claim 7, wherein:
automatically padding the antenna cell comprises automatically padding the antenna cell based on determining that an area constraint of the design entity is satisfied.

11. The program product of claim 10, wherein the program code causes the data processing system to perform:
based on determining that the area constraint of the design entity is not satisfied, placing the antenna cell without padding in the floorplan of the integrated circuit design.

12. The program product of claim 7, wherein the diffusion region is an antenna diode.

13. A data processing system, comprising:
processing circuitry; and
a storage device communicatively coupled to the processing; and
program code stored within the storage device and executable by the processing circuitry of the data processing system to cause the data processing system to perform placement for a hierarchical integrated circuit design including at least an upper hierarchy level, an intermediate hierarchy level, and a lower hierarchy level, said lower hierarchy level including a design entity including at an antenna diode, wherein the program code causes the data processing system to perform placement for integrated circuitry bounded by the design entity by:
determining whether or not an antenna cell containing the antenna diode has any adjoining cell containing a diffusion region connected to a chip package pin; and
based on a determination that the antenna cell has an adjoining cell containing a diffusion region connected to a chip package pin, automatically padding the antenna cell with sufficient padding to satisfy a minimum antenna cell spacing rule and assigning the antenna cell location within a floorplan of the integrated circuit design.

14. The data processing system of claim 13, wherein automatically padding the antenna cell includes updating a design of the antenna cell to include the padding.

15. The data processing system of claim 13, wherein automatically padding the antenna cell includes surrounding the antenna cell with the padding.

16. The data processing system of claim 13, wherein:
automatically padding the antenna cell comprises automatically padding the antenna cell based on determining that an area constraint of the design entity is satisfied.

17. The data processing system of claim 16, wherein the program code causes the data processing system to perform:
based on determining that the area constraint of the design entity is not satisfied, placing the antenna cell without padding in the floorplan of the integrated circuit design.

18. The data processing system of claim 13, wherein the diffusion region is an antenna diode.
